(19) United States
(12) Patent Application Publication
(10) Pub. No.: US 2022/0209754 A1
(43) Pub. Date: Jun. 30, 2022

(54) MULTI OUTPUT GPIO RECEIVER

(71) Applicant: TEXAS INSTRUMENTS INCORPORATED, Dallas, TX (US)

(72) Inventors: Krishna Reddy Mudimela Venkata, Bangalore (IN); Jakeerali Shaik, Bangalore (IN); Sneha Shetty, Bangalore (IN); Swathy Lal, CV raman nagar (IN)

(21) Appl. No.: 17/179,707

(22) Filed: Feb. 19, 2021

(30) Foreign Application Priority Data
Dec. 31, 2020 (IN) 202141000012

(51) Int. Cl. H03K 3/3565; H03K 5/06; H03K 19/00

(52) U.S. Cl. CPC H03K 3/3565; H03K 19/018521; H03K 19/0013; H03K 5/06

(57) ABSTRACT

An assembly includes a signal input, a signal output, a pull-up stack coupled to the signal input and to the signal output, a pull-down stack coupled to the signal input and to the signal output, and a hysteresis assembly coupled to the pull-up stack and to the pull-down stack. The pull-up stack comprises a pair of metal oxide semiconductor field-effect transistors (transistors) coupled in series, each transistor of the pair of transistors comprising a gate coupled to the signal input. The pull-down stack comprises a plurality of transistors coupled in series, the plurality of transistors comprising: a first transistor comprising a gate coupled to the signal input, a second transistor comprising a gate coupled to the signal input, and a third transistor. The hysteresis assembly comprises a pair of transistors, each transistor of the pair of transistors of the hysteresis assembly having a gate coupled to the signal output.

### CROSS-REFERENCE TO RELATED APPLICATIONS

This application claims the benefit of and priority to IN Application number 202141000012 filed Dec. 31, 2020. The disclosure of the above application is incorporated herein by reference.

### BACKGROUND

A general-purpose input-output (GPIO) device in receive mode detects digital signals transmitted by, for example, complementary metal oxide semiconductor (CMOS) or transistor-transistor logic (TTL) drivers. Noise picked up in a signal propagated to the GPIO input can be propagated to the output of the GPIO device when the signal is close to the decision threshold of the GPIO device. In addition, the number of components in the GPIO device can affect the delay exhibited by the device.

### SUMMARY

In accordance with one aspect, an assembly comprises a signal input, a signal output, a pull-up stack coupled to the signal input and to the signal output, a pull-down stack coupled to the signal input and to the signal output, and a hysteresis assembly coupled to the pull-up stack and to the pull-down stack. The pull-up stack comprises a pair of transistors coupled in series, each transistor of the pair of transistors comprising a gate coupled to the signal input. The pull-down stack comprises a plurality of transistors coupled in series, the plurality of transistors comprising: a first transistor comprising a gate coupled to the signal input, a second transistor comprising a gate coupled to the signal input, and a third transistor. The hysteresis assembly comprises a pair of transistors, each transistor of the pair of transistors of the hysteresis assembly having a gate coupled to the signal output.

In accordance with another aspect, a configurable circuit comprises a first plurality of transistors coupled in series and a second plurality of transistors coupled in series, wherein the first plurality of transistors is coupled in series with the second plurality of transistors. An enable transistor is coupled in series with the second plurality of transistors. The configurable circuit also comprises a signal input coupled to a gate terminal of each transistor of the first plurality of transistors and to a gate terminal of each transistor of the second plurality of transistors and comprises a signal output coupled to a drain terminal of a first transistor of the first plurality of transistors and to a drain terminal of a first transistor of the second plurality of transistors. A hysteresis assembly is coupled to the first plurality of transistors, to the second plurality of transistors, and to a voltage output. The hysteresis assembly comprises a first transistor comprising a gate terminal coupled to the voltage output and a second transistor comprising a gate terminal coupled to the voltage output

### BRIEF DESCRIPTION OF THE DRAWINGS

In the drawings:

FIG. 1 is a block diagram illustrating a configurable Schmitt trigger.

FIG. 2 is a schematic diagram of a GPIO receiver according to an embodiment.

FIG. 3 is a flowchart illustrating a method of operating a configurable Schmitt trigger.

FIG. 4 is a plot showing a correlation of an input voltage to an output voltage of the GPIO receiver of FIG. 2 during a non-hysteresis mode of operation according to an embodiment.

FIG. 5 is a plot showing a correlation of an input voltage to an output voltage of the GPIO receiver of FIG. 2 during a hysteresis mode of operation according to an embodiment.

### DETAILED DESCRIPTION

In an embodiment, a complementary metal-oxide-semiconductor (CMOS) integrated circuity technology Schmitt trigger circuit may be configured into a plurality of operating modes. In a first operating mode, the circuit is disabled whereby the output of the circuit does not respond to changes to a signal at the input of the circuit. In a second operating mode, the circuit is configured as an amplifier that amplifies the signal at the input to produce a signal at the output, and the signal at the output exhibits substantially no hysteresis. In a third operating mode, the circuit is configured as a Schmitt trigger. In this mode, the circuit amplifies the signal at the input to produce the signal at the output, and the output exhibits substantial hysteresis. In an embodiment, the circuit may be used as a GPIO receiver circuit.

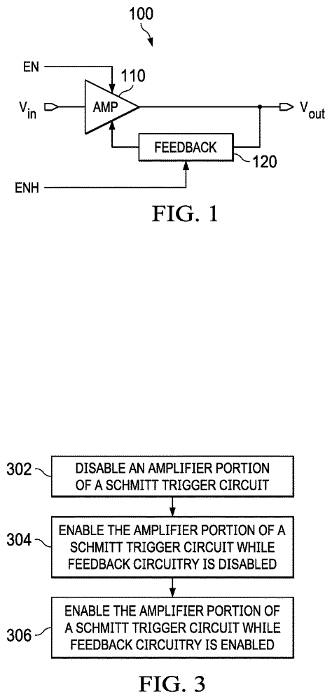

FIG. 1 is a block diagram illustrating a configurable Schmitt trigger. In FIG. 1, configurable circuit 100 includes amplifier circuitry 110 and feedback circuitry 120. Amplifier circuitry receives an input voltage V_{IN} and produces an output voltage V_{OUT}. Because the V_{OUT} saturates at the positive and negative supply voltages (not shown in FIG. 1), the amplifier circuitry 110 may only act as an amplifier over a range of V_{IN} voltages.

In an embodiment, amplifier circuitry 110 receives an enable signal EN that selectively enables and disables amplifier circuitry 110. When EN enables amplifier circuitry 110, amplifier circuitry 110 is operational to drive V_{OUT} based on V_{IN}. When EN disable amplifier circuitry 110, amplifier circuitry 110 and V_{OUT} does not respond to changes to V_{IN}.

Feedback circuitry 120 receives an enable signal HEN that selectively enables and disables feedback circuitry 120. When HEN enables feedback circuitry 120, feedback circuitry 120 is operational. When feedback circuitry 120 is operational, feedback circuitry 120 affects the operation of amplifier circuitry 110 such that V_{OUT} produced by configurable circuitry 100 exhibits substantial hysteresis (e.g., path dependence) as V_{IN} is swept back and forth over a range of voltages (e.g., between a first voltage level representing a logical “0” and a second voltage level representing a logical “1”, and back).

When HEN disables feedback circuitry 120, feedback circuitry 120 is not operational. When feedback circuitry 120 is not operating, feedback circuitry 120 does not substantially affect the operation of amplifier circuitry 110. Thus, V_{OUT} produced by configurable circuitry 100 exhibits little or no hysteresis as V_{IN} is swept back and forth over the range of voltages (e.g., between a first voltage level representing a logical “0” and a second voltage level representing a logical “1”, and back).

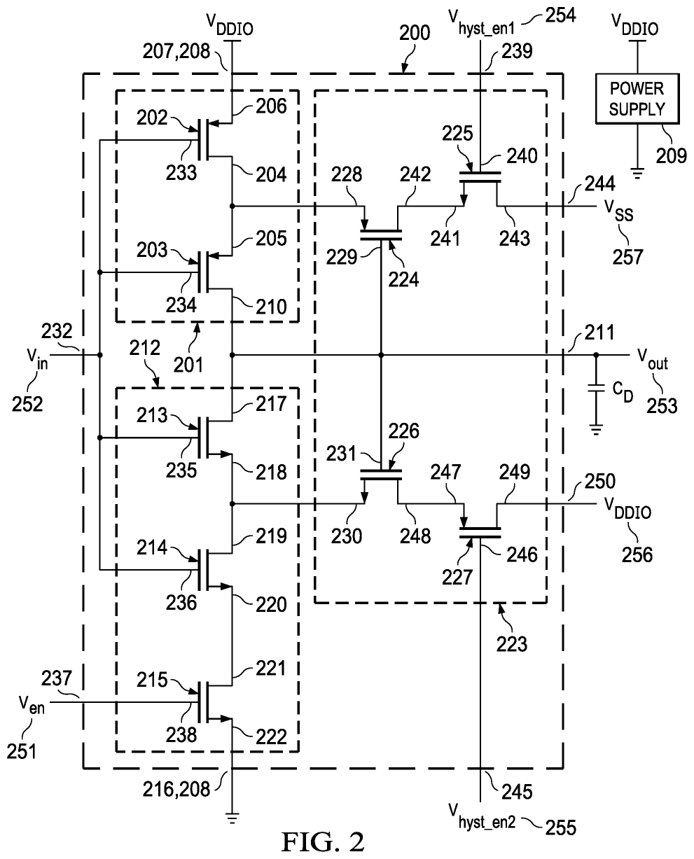

FIG. 2 is a schematic diagram of a GPIO receiver 200 according to an embodiment. GPIO receiver 200 may be an example implementation of configurable circuitry 100. GPIO receiver 200 includes a combination of a hysteresis receiver and a non-hysteresis receiver into a single receiver. GPIO receiver 200 includes a pull-up stack 201 having a pair of serially coupled transistors (e.g., metal oxide semiconductor field-effect transistors (MOSFETs)) 202, 203. Transistors 202, 203 include p-type transistors (e.g., p-type MOSFETs) with the drain terminal 204 of transistor 202 coupled with the source terminal 205 of transistor 203. As used herein, p-type transistors are those created by doping with an electron acceptor element during manufacture. The source terminal 206 of the transistor 202 is coupled to a first input or node 207 of a supply voltage bus 208 of the GPIO receiver 200 that may be connected, for example, to a first voltage of a power supply 209 such as VDDIO. The drain terminal 210 of the transistor 203 is coupled to a signal output 211 of the GPIO receiver 200.

A pull-down stack 212 of the GPIO receiver 200 has a plurality of transistors 213, 214, 215 and is coupled between the signal output 211 and a second input or node 216 of the supply voltage bus 208 coupled to a second voltage of the power supply 209 such as signal ground. Transistors 213, 214, 215 include n-type transistors (e.g., NMOSs). As used herein, n-type transistors are those created by doping with an electron donor element during manufacture. The drain terminal 217 of the transistor 213 is coupled to the signal output 211 and to the drain terminal 210 of the transistor 203. The source terminal 218 of the transistor 213 is coupled to the drain terminal 219 of the transistor 214, and the source terminal 220 of the transistor 214 is coupled to the drain terminal 221 of the enable transistor 215. The source terminal 222 of the transistor 215 is coupled to the second node 216.

GPIO receiver 200 includes a hysteresis assembly 223 of transistors 224, 225, 226, 227 for operating the GPIO receiver 200 in a hysteresis mode. Transistors 224 and 227 are p-type transistors, and transistors 225 and 226 are n-type transistors. The source terminal 228 of the transistor 224 is coupled to the drain terminal 204 of the transistor 202 and to the source terminal 205 of the transistor 203 while the gate terminal 229 of the transistor 224 is coupled to the signal output 211. The source terminal 230 of the transistor 226 is coupled to the drain terminal 219 of the transistor 214 and to the source terminal 218 of the transistor 213 while the gate terminal 231 of the transistor 226 is coupled to the signal output 211.

GPIO receiver 200 includes a signal input 232 coupled to the gates 233, 234, 235, 236 of respective transistors 202, 203, 213, 214. GPIO receiver 200 also includes an enable control input 237 coupled to the gate terminal 238 of the transistor 215. A first hysteresis enable control input 239 of the GPIO receiver 200 is coupled to the gate terminal 240 of the transistor 225, the source terminal 241 of the transistor 225 is coupled to the drain terminal 242 of the transistor 224, and the drain terminal 243 of the transistor 225 is coupled to a first hysteresis voltage input 244 of the GPIO receiver 200. A second hysteresis enable control input 245 of the GPIO receiver 200 is coupled to the gate terminal 246 of the transistor 227, the source terminal 247 of the transistor 227 is coupled to the drain terminal 248 of the transistor 226, and the drain terminal 249 of the transistor 227 is coupled to a second hysteresis voltage input 250 of the GPIO receiver 200.

FIG. 3 is a flowchart illustrating a method of operating a configurable Schmitt trigger. The steps illustrated in FIG. 3 may be performed by, for example, configurable circuit 100, configurable circuit 200, and/or their components. In a first mode of operation (e.g., a disabled mode), an amplifier portion of a Schmitt trigger circuit is disabled (302). For example, the operation of transistors 202, 203 and transistors 213-215 may be disabled by applying a logical “0” (e.g., V_{SS}) of a voltage enable signal 251 (e.g., Vₑₙ) on the gate terminal 238 of the transistor 215. In this disabled mode, an input voltage 252 (e.g., Vᵢₙ) applied to the signal input 232 is not processed by the GPIO receiver 200 to produce an output voltage 253 (e.g., V_{OUT}) on signal output 211.

In a second mode of operation (e.g., a non-hysteresis mode), the amplifier portion of a Schmitt trigger circuit is enabled while feedback circuitry is disabled (304). For example, the operation of transistors 202, 203 and transistors 213-215 may be enabled by applying a logical “1” (e.g., V_{DDIO}) of the voltage enable signal 251, Vₑₙ, on the gate terminal 238 the transistor 215. In addition, the operation of transistors 224-225, 526-527 may be disabled by applying a logical “0” (e.g., V_{SS}) of a first hysteresis enable signal (e.g., V_{hyst_en1}) on the gate terminal 240 of the transistor 225 and by applying a logical “1” (e.g., V_{DDIO}) of a second hysteresis enable signal (e.g., V_{hyst_en2}) on the gate terminal 246 of the transistor 227. In this second mode, an input voltage 252 (e.g., Vᵢₙ) applied to the signal input 232 is processed by the GPIO receiver 200 to produce an output voltage 253 (e.g., Vₒᵤₜ) on signal output 211.

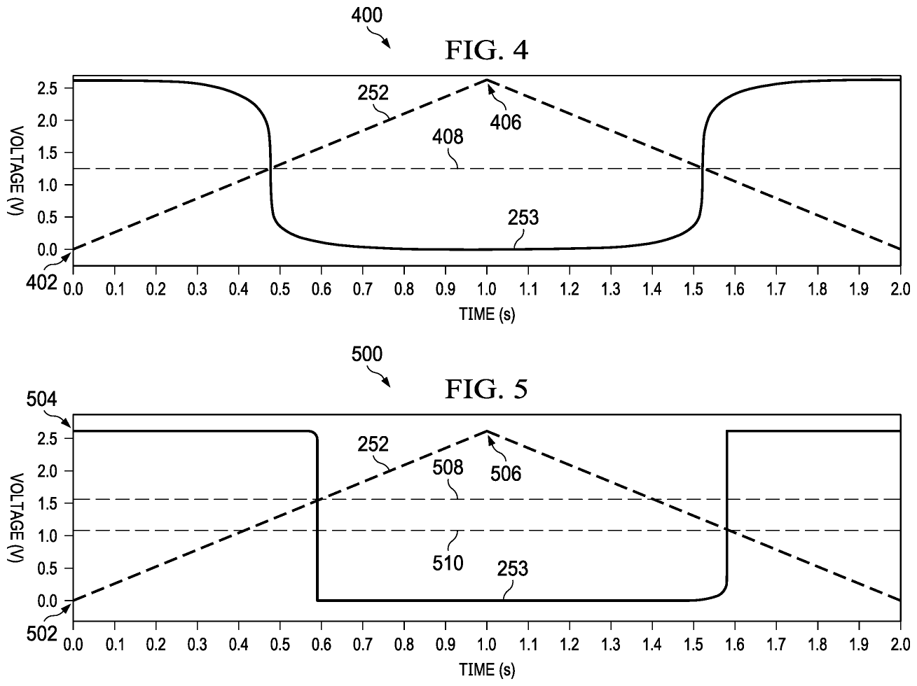

Referring to FIG. 4, a plot 400 is shown of a correlation of the input voltage 252 (Vᵢₙ) to the output voltage 253 (Vₒᵤₜ) during the non-hysteresis mode of operation according to an embodiment. As illustrated, the input voltage 252 starts at time of 0 seconds at its low value 402, which, in the illustrated example, is a voltage of substantially 0 volts. The output voltage 253 correspondingly starts at the time of 0 seconds at its high value 404, which, in the illustrated example, is a voltage of over 2.5 volts. As the voltage of the input voltage 252 increases toward its high value 406 (e.g., over 2.5 volts), the voltage approaches a trip point voltage 408. During this approach, the output voltage 253 begins to decrease, though its value may still be considered to be a high state (e.g., a logical 1). In response to the input voltage 252 reaching the trip point voltage 408, the output voltage 253 switches from a voltage value above the trip point voltage 408 to a voltage value below the trip point voltage 408, and the output voltage 253 may be considered to be in a low state (e.g. a logical 0).

Since the operation is in a non-hysteresis mode, the trip point voltage 408 does not change in response to either the input voltage 252 or the output voltage 253. Accordingly, as the voltage of the input voltage 252 decreases toward its low value 402, the voltage again approaches the trip point voltage 408. In response to the input voltage 252 reaching the trip point voltage 408, the output voltage 253 switches from a voltage value below the trip point voltage 408 to a voltage value above the trip point voltage 408, which may be considered once again to be in the high state. Accordingly, fluctuations in the input voltage 252 about the trip point voltage 408 may cause corresponding fluctuations in the high/low state of the output voltage 253.

Referring again to FIG. 3, in a third mode of operation (e.g., a hysteresis mode) configured to address such effects resulting from fluctuations in the input voltage 252, the amplifier portion of a Schmitt trigger circuit is enabled while feedback circuitry is enabled (306). For example, the operation of transistors 202, 203 and transistors 213-215 may be enabled by applying a logical “1” (e.g., V_{DDIO}) of the voltage enable signal 251, Vₑₙ, on the gate terminal 238 the transistor 215. In addition, the operation of transistors 224-225, 526-527 may be enabled by applying a logical “1” (e.g., V_{DDIO}) of the first hysteresis enable signal, V_{hyst_en1}, on the gate terminal 240 of the transistor 225 and by applying a logical “0” (e.g., V_{SS}) of the second hysteresis enable signal, V_{hyst_en2}, on the gate terminal 246 of the transistor 227. In this third, hysteresis mode of operation, the decision threshold of the GPIO receiver 200 alternates between a pair of values based on a high hysteresis reference 256 and a low hysteresis reference 257 respectively applied to the second hysteresis voltage inputs 250, 244. In this manner, large voltage swings of the output voltage 253 (e.g., from zero volts to V_{DDIO} and vice-versa) when the input voltage 252 varies about the decision threshold due to small fluctuations in the input voltage 252 can be minimized or eliminated.

FIG. 5 illustrates a plot 500 showing of a correlation of the input voltage 252 (Vᵢₙ) to the output voltage 253 (Vₒᵤₜ) during the hysteresis mode of operation according to an embodiment. As illustrated, the input voltage 252 starts at time of 0 seconds at its low value 502, which, in the illustrated example, is a voltage of substantially 0 volts. The output voltage 253 correspondingly starts at the time of 0 seconds at its high value 504, which, in the illustrated example, is a voltage of over 2.5 volts. As the voltage of the input voltage 252 increases toward its high value 506 (e.g., over 2.5 volts), the voltage approaches a trip point voltage 508. During this approach, the output voltage 253 may be considered to be a high state (e.g., a logical 1). In response to the input voltage 252 reaching the trip point voltage 508, the output voltage 253 switches from a voltage value above the trip point voltage 508 to a voltage value below the trip point voltage 508, and the output voltage 253 may be considered to be in a low state (e.g. a logical 0).

Operation in the hysteresis mode causes a change in voltage value at which the trip point will cause the output voltage 253 to change to its high state. As illustrated, the value of the trip point is changed to a second trip point voltage 510, which is lower than the trip point voltage 508. In response to the input voltage 252 reaching the trip point voltage 510, the output voltage 253 switches from a voltage value below the trip point voltage 510 to a voltage value above the trip point voltage 510 and may be considered once again to be in the high state. After the input voltage 252 crosses the trip point voltage 510, the first, higher trip point voltage 508 is activated again, and the output voltage 253 will not transition to its low state while the input voltage 252 is below the trip point voltage 508. Accordingly, fluctuations in the input voltage 252 about each trip point voltage 508, 510 eliminate corresponding fluctuations in the high/low state of the output voltage 253.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

1. An assembly comprising:
a signal input;
a signal output;
a pull-up stack coupled to the signal input and to the signal output, the pull-up stack comprising a pair of transistors coupled in series, each transistor of the pair of transistors comprising a gate coupled to the signal input;
a pull-down stack coupled to the signal input and to the signal output, the pull-down stack comprising a plurality of transistors coupled in series, the plurality of transistors comprising:
a first transistor comprising a gate coupled to the signal input;
a second transistor comprising a gate coupled to the signal input; and
a third transistor; and
a hysteresis assembly coupled to the pull-up stack and to the pull-down stack and comprising a pair of transistors, each transistor of the pair of transistors of the hysteresis assembly comprising a gate coupled to the signal output.

2. The assembly of claim 1 further comprising:
a supply voltage bus comprising:
a first node coupleable to a first power supply voltage; and
a second node coupleable to a second power supply voltage; and
wherein the pull-up stack and the pull-down stack are coupled in series between the first node and the second node.

3. The assembly of claim 1 further comprising:
a first hysteresis control input;
a second hysteresis control input; and
wherein the hysteresis assembly further comprises:
a first hysteresis control transistor coupled to a first transistor of the pair of transistors of the hysteresis assembly and to the first hysteresis control input; and
a second hysteresis control transistor coupled to a second transistor of the pair of transistors of the hysteresis assembly and to the second hysteresis control input.

4. The assembly of claim 3, wherein a source terminal of the first transistor of the pair of transistors of the hysteresis assembly is coupled to a drain terminal of a first transistor of the pair of transistors of the pull-up stack and to a source terminal of a second transistor of the pair of transistors of the pull-up stack; and
wherein a source terminal of the second transistor of the pair of transistors of the hysteresis assembly is coupled to a drain terminal of a first transistor of the plurality of transistors of the pull-down stack and to a source terminal of a second transistor of the plurality of transistors of the pull-down stack.

5. The assembly of claim 3 further comprising:
a first hysteresis voltage input coupled to the first hysteresis control transistor; and
a second hysteresis voltage input coupled to the second hysteresis control transistor.

6. The assembly of claim 1 further comprising an enable control input coupled to a gate of the third transistor.

7. The assembly of claim 1, wherein each transistor of the pull-up stack comprises a p-type transistor; and
wherein each transistor of the pull-down stack comprises an n-type transistor.

8. The assembly of claim 1, wherein the pull-up stack is comprised of the pair of transistors.

9. The assembly of claim 8, wherein the pull-down stack is comprised of the first, second, and third transistors of the pull-down stack.

10. The assembly of claim 9, wherein the hysteresis assembly is comprised of the pair of transistors of the hysteresis assembly.

11. A configurable circuit comprising:
a first plurality of transistors coupled in series;
a second plurality of transistors coupled in series, wherein the first plurality of transistors is coupled in series with the second plurality of transistors;
an enable transistor coupled in series with the second plurality of transistors;
a signal input coupled to a gate terminal of each transistor of the first plurality of transistors and to a gate terminal of each transistor of the second plurality of transistors;
a signal output coupled to a drain terminal of a first transistor of the first plurality of transistors and to a drain terminal of a first transistor of the second plurality of transistors; and
a hysteresis assembly coupled to the first plurality of transistors, to the second plurality of transistors, and to a voltage output, the hysteresis assembly comprising:
a first transistor comprising a gate terminal coupled to the voltage output; and
a second transistor comprising a gate terminal coupled to the voltage output.

12. The configurable circuit of claim 11 further comprising:
a source terminal of the first transistor of the hysteresis assembly coupled with the first plurality of transistors; and
a source terminal of the second transistor of the hysteresis assembly coupled with the second plurality of transistors.

13. The configurable circuit of claim 12 further comprising:
a source terminal of a third transistor of the hysteresis assembly coupled with a drain terminal of the first transistor of the hysteresis assembly; and
a source terminal of a fourth transistor of the hysteresis assembly coupled with a drain terminal of the second transistor of the hysteresis assembly.

14. The configurable circuit of claim 13 further comprising:
a gate terminal of the third transistor coupled with a first hysteresis enable control input; and
a gate terminal of the fourth transistor coupled with a second hysteresis enable control input.

15. The configurable circuit of claim 13, wherein the hysteresis assembly is comprised of the first, second, third, and fourth transistors.

16. The configurable circuit of claim 11, wherein the first plurality of transistors is comprised of the first transistor of the first plurality of transistors and a second transistor of the first plurality of transistors.

17. The configurable circuit of claim 16, wherein the first and second transistors of the first plurality of transistors comprise p-type transistors.

18. The configurable circuit of claim 11, wherein the second plurality of transistors is comprised of the first transistor of the second plurality of transistors and a second transistor of the second plurality of transistors.

19. The configurable circuit of claim 18, wherein the first and second transistors of the second plurality of transistors comprise n-type transistors.

20. The configurable circuit of claim 19, wherein the enable transistor comprises an n-type transistor.
